(19) United States
(12) Patent Application Publication
(10) Pub. No.: US 2026/0205110 A1
(43) Pub. Date: Jul. 16, 2026

(54) OPEN-DRAIN OUTPUT DRIVER CIRCUIT WITH CONSTANT VOLTAGE SLEW RATE

(71) Applicant: Beijing Galaxy-CAS Technology Co., Ltd., Beijing (CN)

(72) Inventors: Kailun ZHENG, Beijing (CN); Guiliang GUO, Beijing (CN)

(73) Assignee: Beijing Galaxy-CAS Technology Co., Ltd., Beijing (CN)

(21) Appl. No.: 19/439,674

(22) Filed: Jan. 5, 2026

(30) Foreign Application Priority Data
Jan. 14, 2025 (CN) 202510057776.5

(51) Int. Cl. H03K 17/16

(52) U.S. Cl. CPC H03K 17/165; H03K 2217/0027

(57) ABSTRACT

Provided is an open-drain output driver circuit with a constant voltage slew rate. The open-drain output driver circuit with a constant voltage slew rate includes a pull-up path, a pull-down path, a bleed path, and a drive transistor that act on a target node, where a current sensing resistor is connected in series in the pull-up path; and the current sensing resistor is configured to sense a path current in real time, and feed a sensed path current back as a gate-source voltage of a corresponding switch transistor in the bleed path, thereby controlling a shunting extent of the bleed path with respect to the pull-up path to maintain a limited and constant voltage slew rate.

### RELATED APPLICATION DATA

The present application claims priority to Chinese Patent Application No. 202510057776.5 filed to the China National Intellectual Property Administration on January 14, 2025, the entire contents of the above application is hereby incorporated by reference into the present application.

### TECHNICAL FIELD

The present disclosure relates to the technical field of electronic devices, and in particular to an open-drain output driver circuit with a constant voltage slew rate.

### BACKGROUND

In modern electronic devices and communication systems, open-drain outputs are widely used in various communication buses such as 1-WIRE, I2C, and I3C. Hence, the driver circuit at an open-drain output port is an indispensable and crucial component in the entire interface circuit. For a signal on the communication bus, a higher voltage slew rate and a steeper signal edge will result in more high-frequency components. This means that more electromagnetic interference (EMI) will be generated to affect operation of adjacent chips. Additionally, for bus systems with longer wiring lengths like 1-WIRE, excessively steep signal edges may further cause overshoot and ringing of the buses. If the communication signal can achieve a limited and constant voltage slew rate, the reliability and electromagnetic compatibility (EMC) of the communication bus can be effectively improved.

Therefore, a simpler and more efficient open-drain output driver circuit with a constant voltage slew rate is urgently desired.

### SUMMARY

An objective of the present disclosure is to provide an open-drain output driver circuit with a constant voltage slew rate, to solve the problem that an additional bandgap reference module is required to generate a reference current independent of a power voltage and an operating temperature, and constancy of a slew rate is entirely determined by intrinsic performance of the reference current in the prior art.

To achieve the above objective, the present disclosure provides the following technical solutions:

According to a first aspect, the present disclosure provides an open-drain output driver

circuit with a constant voltage slew rate, including:

a pull-up path, a pull-down path, a bleed path, and a drive transistor that act on a target node, where

a second resistor is connected in series in the pull-up path; the second resistor is a current sensing resistor; and the second resistor is configured to sense a path current in real time, and feed a sensed path current back as a gate-source voltage of a corresponding switch transistor in the bleed path, thereby controlling a shunting extent of the bleed path with respect to the pull-up path to maintain a limited and constant voltage slew rate.

Optionally, the pull-up path includes a first switch transistor, a first resistor, and the second resistor; and the first resistor and the second resistor are connected in series between the first switch transistor and the target node;

the pull-down path includes a second switch transistor; and a gate of the first switch transistor is connected to a gate of the second switch transistor;

the bleed path includes the first switch transistor, the first resistor, and a fourth switch transistor; one terminal of the first resistor is connected to the first switch transistor; and another terminal of the first resistor is connected to the fourth switch transistor; and

the drive transistor includes a third switch transistor and a Miller capacitor; a gate of the third switch transistor is connected to the target node; one terminal of the Miller capacitor is connected to the gate of the third switch transistor; and another terminal of the Miller capacitor is connected to a drain of the third switch transistor.

Optionally, a node voltage of the target node serves as a gate voltage of the drive transistor, and is used to control a turn-on level of the drive transistor.

Optionally, if data input of the open-drain output driver circuit is a logic 1, the first switch transistor is turned off, and the second switch transistor is turned on; the target node is discharged through the pull-down path to a ground voltage, such that the third switch transistor is turned off; an open-drain output port shows a high impedance; and a bus voltage is pulled up to a power voltage by an external pull-up resistor.

Optionally, if data input is a logic 0, the second switch transistor is turned off, and the first switch transistor is turned on; the target node is charged through the pull-up path to a power voltage, such that the third switch transistor is turned on; an open-drain output port is in a low-impedance connection to the ground; and a bus voltage is pulled down to a voltage around a ground voltage by the drive transistor.

Optionally, when a reference current is not used to provide the path current of the pull-up path, the path current of the pull-up path changes with a power voltage and an operating temperature; the path current of the pull-up path increases exponentially at a low temperature and a high voltage; and the path current of the pull-up path decreases exponentially at a high temperature and a low voltage.

Optionally, if the path current of the pull-up path is excessively large, the fourth switch transistor is turned on, and the bleed path is activated.

Optionally, as the path current of the pull-up path increases, a gate-source voltage of the fourth switch transistor rises, and an on-resistance of the fourth switch transistor as a switch decreases; and a higher current shunted by the bleed path indicates a greater extent of slowing down a charging speed of the target node.

Optionally, when a current shunted by the bleed path is greater than a preset current value, the path current of the pull-up path decreases, voltages at two terminals of the second resistor drop, a gate-source voltage of the fourth switch transistor drops, and an on-resistance of the fourth switch transistor as a switch increases; and as the current shunted by the bleed path decreases, an extent of slowing down a charging speed of the target node is weakened.

Compared with the prior art, the open-drain output driver circuit with a constant voltage slew rate provided by the present disclosure includes the pull-up path, the pull-down path, the bleed path, and the drive transistor that act on the target node. The current sensing resistor is connected in series in the pull-up path. The current sensing resistor is configured to sense the path current in real time, and feed a sensed path current back as the gate-source voltage of a corresponding one of the switch transistors in the bleed path, thereby controlling the shunting extent of the bleed path with respect to the pull-up path to maintain the limited and constant voltage slew rate. The present disclosure senses the path current in real time through the current sensing resistor connected in series in the pull-up path, and feeds the sensed result back as the gate-source voltage of the fourth switch transistor, thereby controlling the shunting extent of the bleed path for the pull-up path to realize the limited and constant voltage slew rate. Without the additional bandgap reference module for generating the reference current, and without any comparator or switch array, the present disclosure effectively saves the layout area, and reduces the chip cost. Moreover, the closed-loop control provided by the present disclosure has advantages of accurate control and strong anti-interference capability, effectively achieving the constant voltage slew rate of the open-drain output port, thereby improving the reliability and EMC of the communication bus.

### BRIEF DESCRIPTION OF THE DRAWINGS

The accompanying drawings described herein are provided for further understanding of the present disclosure, and constitute a part of the present disclosure. The exemplary embodiments and illustrations of the present disclosure are intended to explain the present disclosure, but do not constitute inappropriate limitations to the present disclosure. In the accompanying drawings:

FIG. 1 is a schematic view of a conventional open-drain output driver circuit with an unlimited slew rate according to the prior art;

FIG. 2 is a schematic view of an open-drain output driver circuit according to the prior art; and

FIG. 3 is a schematic view of an open-drain output driver circuit with a constant voltage slew rate according to the present disclosure.

Reference numerals:

1-pull-up path, 2-pull-down path, 3-bleed path, 4-drive transistor, M1-first switch transistor, M2-second switch transistor, M3-third switch transistor, M4-fourth switch transistor, R1-first resistor, R2-second resistor, C-Miller capacitor, and G-target node.

### DETAILED DESCRIPTION OF THE EMBODIMENTS

For the ease of clearly describing the technical solutions in the embodiments of the present disclosure, words "first", "second" and the like are used in the embodiments of the present disclosure to distinguish same or similar items that are basically the same in function and effect. For example, the first threshold and the second threshold are merely for the purpose of distinguishing different thresholds, rather than limiting a sequential order. Those skilled in the art should understand that the terms such as "first" and ''second'' are not intended to limit the number and execution sequence and are not necessarily intended to be different.

It is to be noted that the words "exemplary'' or "for example'' or the like represents serving as an example, instance or illustration in the present disclosure. Any embodiment or design solution described herein as ''exemplary'' or "for example'' should not be construed as being more preferred or advantageous over other embodiments or design solutions. Exactly, use of "for example", "example", or the like is intended to present a related concept in a specific manner.

In the present disclosure, the term ''at least one" refers to one or more types, and the term "multiple" refers to two or more types. The term "and/or" is an association relationship for describing associated objects, and represents that three relationships may exist, for example, A and/or B may represent that: A exists alone, A and B exist at the same time, and B exists alone. The character "/" usually indicates an "or" relationship between associated objects. The term "at least one of the following items" or similar expression refers to any combination of these items, including any combination of single items or plural items. For example, at least one of a, b or c may be expressed as: a, b, c, a+b, a+c, b+c or a+b+c; and the a, b and c may be the single items, and may also be the plural items.

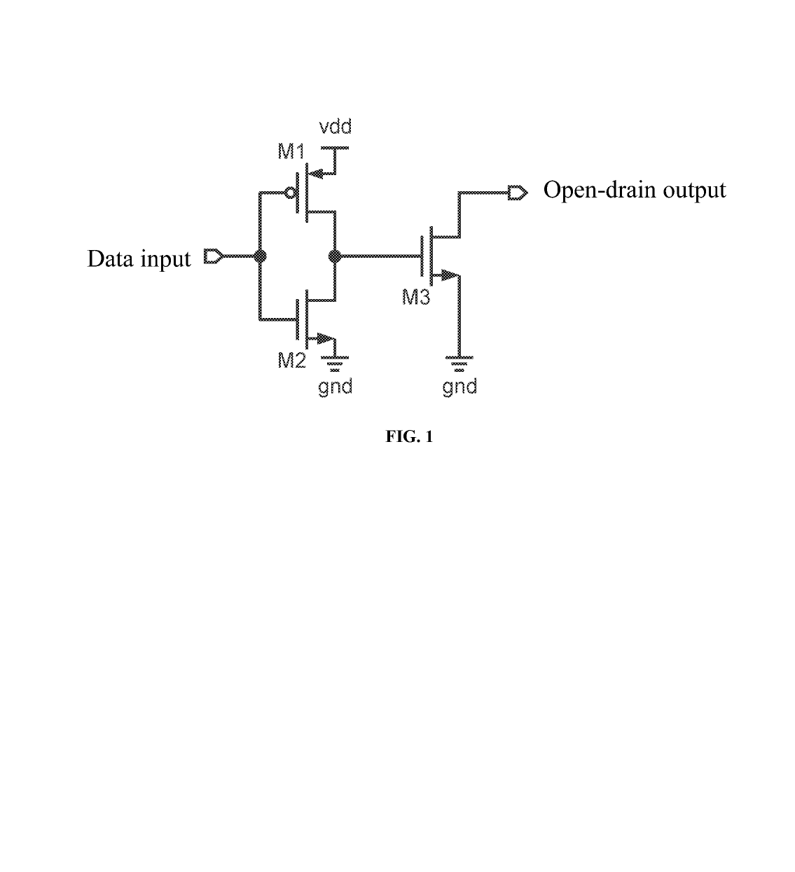

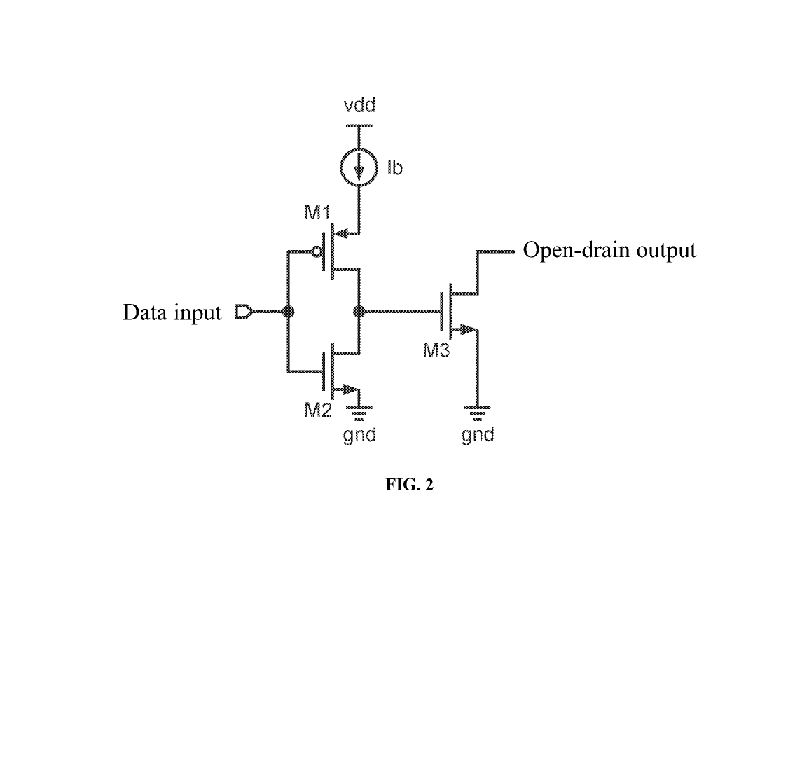

FIG. 1 shows a conventional open-drain output driver circuit with an unlimited slew rate. The input signal directly controls a gate voltage of a drive transistor 4 after passing through an inverter. FIG. 2 shows an existing technology with a limited slew rate. With a reference current in the pull-up path 1 of the inverter, and with a constant current for charging a capacitor to control the rise of a gate voltage of a drive transistor 4, a voltage slew rate of an open-drain output signal is limited to be constant. This solution is advantageous for the limited and constant slew rate, but has the drawback that an additional bandgap reference module is required to generate the reference current independent of a power voltage and an operating temperature, and constancy of the slew rate is entirely determined by intrinsic performance of the reference current.

In order to solve the problems in the prior art, the present disclosure provides an open-drain output driver circuit with a constant voltage slew rate. The solutions provided by the embodiment of the present disclosure will be described below with reference to the accompanying drawings:

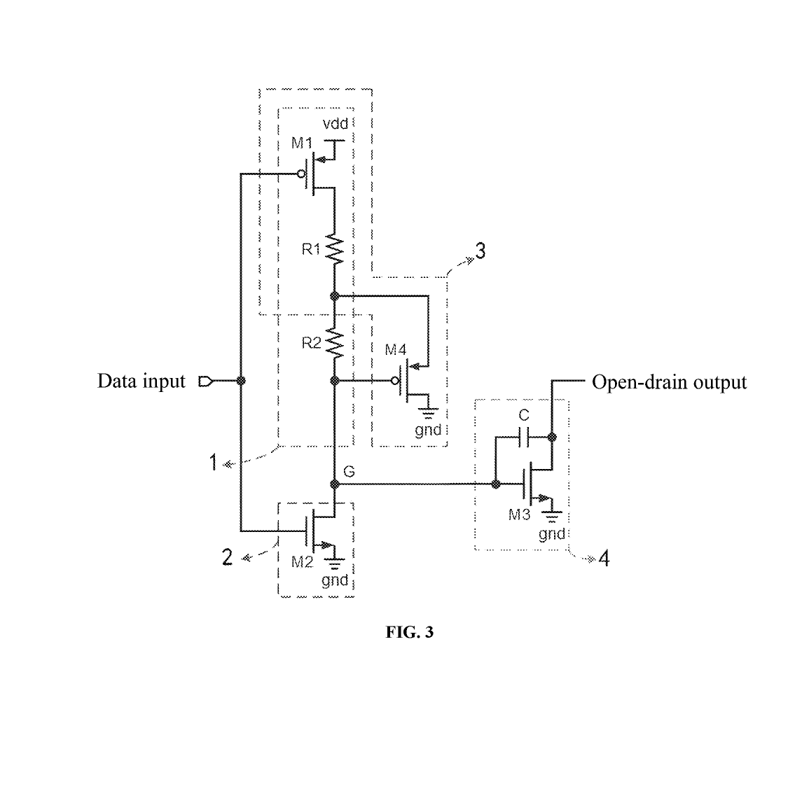

The present disclosure provides an open-drain output driver circuit with a constant voltage slew rate. As shown in FIG. 3, the open-drain output driver circuit with a constant voltage slew rate may include:

a pull-up path 1, a pull-down path 2, a bleed path 3, and a drive transistor 4 that act on a target node G.

A second resistor R2 is connected in series in the pull-up path 1. The second resistor R2 is a current sensing resistor. The second resistor R2 is configured to sense a path current in real time, and feed a sensed path current back as a gate-source voltage of a corresponding switch transistor in the bleed path 3, thereby controlling a shunting extent of the bleed path 3 with respect to the pull-up path 1 to maintain a limited and constant voltage slew rate.

Based on the structural view in FIG. 3, the open-drain output driver circuit with a constant voltage slew rate provided by the embodiment of the present disclosure can further be divided, which is described below.

The pull-up path 1 includes a first switch transistor M1, a first resistor R1, and the second resistor R2. The first resistor R1 and the second resistor R2 are connected in series between the first switch transistor M1 and the target node G.

The first switch transistor M1 may be a P-channel metal-oxide semiconductor (PMOS) switch transistor. The first resistor R1 may be a current limiting resistor. The second resistor R2 may be the current sensing resistor.

The pull-down path 2 includes a second switch transistor M2. A gate of the first switch transistor M1 is connected to a gate of the second switch transistor M2.

The second switch transistor M2 may be an N-channel metal-oxide semiconductor (NMOS) switch transistor.

The bleed path 3 includes the first switch transistor M1, the first resistor R1, and a fourth switch transistor M4. One terminal of the first resistor R1 is connected to the first switch transistor M1. Another terminal of the first resistor R1 is connected to the fourth switch transistor M4.

The fourth switch transistor M4 may be a PMOS switch transistor.

The drive transistor 4 includes a third switch transistor M3 and a Miller capacitor C. A gate of the third switch transistor M3 is connected to the target node G. One terminal of the Miller capacitor C is connected to the gate of the third switch transistor M3. Another terminal of the Miller capacitor C is connected to a drain of the third switch transistor M3.

The number of switch transistors and the number of resistors in the above structure may increase or decrease according to an actual need. The fourth switch transistor M4 may be the PMOS switch transistor, a triode, a switch, a voltage-controlled switch, a voltage-controlled resistor, etc.

Therefore, as shown in FIG. 3, a simple and efficient closed-loop control circuit provided by the present disclosure includes the pull-up path 1, the pull-down path 2, the bleed path 3, and the drive transistor 4. The pull-up path 1 includes the PMOS switch transistor (the first switch transistor M1), the current limiting resistor (the first resistor R1), and the current sensing resistor (the second resistor R2). The pull-down path 2 includes the NMOS switch transistor (the second switch transistor M2). The bleed path 3 includes the PMOS switch transistor (the first switch transistor M1), the current limiting resistor (the first resistor R1), and the PMOS switch transistor (the fourth switch transistor M4). The drive transistor 4 includes the PMOS switch transistor (the third switch transistor M3) and the Miller capacitor C. The pull-up path 1, the pull-down path 2, and the bleed path 3 act on the target node G. A node voltage serves as a gate voltage of the drive transistor 4, and is used to control a turn-on level of the drive transistor 4.

In the structure shown in FIG. 3, the current sensing resistor (the second resistor R2) is added in the pull-up path 1. The current sensing resistor is configured to sense the path current in real time, and feed a sensed path current back as a gate-source voltage of the fourth switch transistor M4, thereby controlling a shunting extent of the bleed path 3 with respect to the pull-up path 1 to maintain the limited and constant voltage slew rate.

The fourth switch transistor M4 is added in the bleed path 3 to realize the closed-loop control effect. Without the additional bandgap reference module for generating the reference current, and without any comparator or switch array, the layout area is effectively saved, and the chip cost is reduced.

Further, for the circuit structure in FIG. 3, the corresponding operating principle is as follows:

If data input of the open-drain output driver circuit is a logic 1, the first switch transistor M1 is turned off, and the second switch transistor M2 is turned on. The target node G is discharged through the pull-down path 2 to a ground voltage gnd, such that the third switch transistor M3 is turned off. At this time, an open-drain output port shows a high impedance, and a bus voltage is pulled up to a power voltage vdd by an external pull-up resistor. Rising time of the bus voltage in this process is entirely determined by the external pull-up resistor and the load capacitor, which is not limited in the present disclosure.

If data input is a logic 0, the second switch transistor M2 is turned off, and the first switch transistor M1 is turned on. The target node G is charged through the pull-up path 1 to a power voltage vdd, such that the third switch transistor M3 is turned on. At this time, an open-drain output port is in a low-impedance connection to the ground, and a bus voltage is pulled down to a voltage around a ground voltage gnd by the drive transistor 4 (the third switch transistor M3). Dropping time of the bus voltage in this process is primarily determined by the charging speed of the target node G. What is limited by the present disclosure is the voltage slew rate in this process.

When a reference current is not used to provide the path current of the pull-up path 1, the path current changes significantly with a power voltage and an operating temperature. The current increases exponentially at a low temperature and a high voltage. The current decreases exponentially at a high temperature and a low voltage. The present disclosure senses the path current in real time through the current sensing resistor connected in series in the pull-up path 1, and feeds the sensed result back as the gate-source voltage of the fourth switch transistor M4, thereby controlling the shunting extent of the bleed path 3 for the pull-up path 1 to realize the limited and constant voltage slew rate.

If the path current of the pull-up path 1 is excessively large, the fourth switch transistor M4 is turned on, and the bleed path 3 is activated. This creates a direct path for the current from the power voltage vdd to the ground voltage gnd, and shunts a part of the current of the pull-up path 1, thereby slowing down the charging speed of the target node G. A higher path current of the pull-up path 1 indicates a higher gate-source voltage of the fourth switch transistor M4, a smaller on-resistance of the fourth switch transistor M4 as a switch, a higher current shunted by the bleed path 3, and a greater extent of slowing down the charging speed of the target node G. When an excessive current is shunted by the bleed path 3, the path current of the pull-up path 1 decreases, and voltages at two terminals of the current sensing resistor (the second resistor R2) drop. That is, the gate-source voltage of the fourth switch transistor M4 drops, and an on-resistance of the fourth switch transistor M4 as a switch increases. As the current shunted by the bleed path 3 decreases, an extent of slowing down a charging speed of the target node G is weakened. The negative feedback process realizes closed-loop control on the voltage slew rate, thereby maintaining the voltage slew rate constant and unchanged.

Therefore, the open-drain output driver circuit with a constant voltage slew rate provided by the present disclosure can realize at least the following technical effects:

1 The present disclosure provides the simple and efficient circuit structure. The fourth switch transistor M4 is added in the circuit to realize the closed-loop control effect. Without the additional bandgap reference module for generating the reference current, and without any comparator or switch array, the layout area is effectively saved, and the chip cost is reduced.

2 The present disclosure is based on the negative feedback closed-loop control. Compared with the conventional open-loop control, the closed-loop control provided by the present disclosure has advantages of accurate control and strong anti-interference capability.

3 The present disclosure can achieve the constant voltage slew rate of the open-drain output port simply and efficiently, thereby improving the reliability and EMC of the communication bus.

Although the present disclosure has been described in combination with the embodiments, those skilled in the art may understand and implement other changes of the embodiments of the present disclosure by checking the accompanying drawings, disclosures and appended claims during implementation of the present disclosure. In the claims, the word "comprising'' does not exclude other components or steps, and the word "a" or "an" does not exclude a plural cases. A single processor or other units may implement a plurality of functions listed in the claims. Some measures are recorded in dependent claims that are different from one another. However, it does not mean that these measure cannot be combined together to achieve a desirable effect.

Although the present disclosure has been described in combination with specific features and embodiments thereof, it is apparent that various modifications and combinations may be made without departing from the spirit and scope of the present disclosure. Correspondingly, the specification and accompanying drawings are merely exemplary descriptions of the present disclosure that are defined by the appended claims, and are deemed as covering any and all of the modifications, changes, combinations or equivalents within the scope of the present disclosure. It will be apparent to those skilled in the art that various modifications and variations can be made to the present disclosure without departing from the spirit and scope of the present disclosure. In this way, if these modifications and variations of the present disclosure fall within the scope of the claims of the present disclosure and equivalent technologies thereof, the present disclosure is further intended to include these modifications and variations.

What is claimed is:

1. An open-drain output driver circuit with a constant voltage slew rate, comprising:
a pull-up path, a pull-down path, a bleed path, and a drive transistor that act on a target node, wherein
a second resistor is connected in series in the pull-up path; the second resistor is a current sensing resistor; and the second resistor is configured to sense a path current in real time, and feed a sensed path current back as a gate-source voltage of a corresponding switch transistor in the bleed path, thereby controlling a shunting extent of the bleed path with respect to the pull-up path to maintain a limited and constant voltage slew rate.

2. The open-drain output driver circuit with a constant voltage slew rate according to claim 1, wherein the pull-up path comprises a first switch transistor, a first resistor, and the second resistor; and the first resistor and the second resistor are connected in series between the first switch transistor and the target node;
the pull-down path comprises a second switch transistor; and a gate of the first switch transistor is connected to a gate of the second switch transistor;
the bleed path comprises the first switch transistor, the first resistor, and a fourth switch transistor; one terminal of the first resistor is connected to the first switch transistor; and another terminal of the first resistor is connected to the fourth switch transistor; and
the drive transistor comprises a third switch transistor and a Miller capacitor; a gate of the third switch transistor is connected to the target node; one terminal of the Miller capacitor is connected to the gate of the third switch transistor; and another terminal of the Miller capacitor is connected to a drain of the third switch transistor.

3. The open-drain output driver circuit with a constant voltage slew rate according to claim 1, wherein a node voltage of the target node serves as a gate voltage of the drive transistor, and is used to control a turn-on level of the drive transistor.

4. The open-drain output driver circuit with a constant voltage slew rate according to claim 2, wherein in response to that data input of the open-drain output driver circuit is a logic 1, the first switch transistor is turned off, and the second switch transistor is turned on; the target node is discharged through the pull-down path to a ground voltage, such that the third switch transistor is turned off; an open-drain output port shows a high impedance; and a bus voltage is pulled up to a power voltage by an external pull-up resistor.

5. The open-drain output driver circuit with a constant voltage slew rate according to claim 2, wherein in response to that data input is a logic 0, the second switch transistor is turned off, and the first switch transistor is turned on; the target node is charged through the pull-up path to a power voltage, such that the third switch transistor is turned on; an open-drain output port is in a low-impedance connection to the ground; and a bus voltage is pulled down to a voltage around a ground voltage by the drive transistor.

6. The open-drain output driver circuit with a constant voltage slew rate according to claim 1, wherein in response to that a reference current is not used to provide the path current of the pull-up path, the path current of the pull-up path changes with a power voltage and an operating temperature; the path current of the pull-up path increases exponentially at a low temperature and a high voltage; and the path current of the pull-up path decreases exponentially at a high temperature and a low voltage.

7. The open-drain output driver circuit with a constant voltage slew rate according to claim 2, wherein in response to that the path current of the pull-up path is excessively large, the fourth switch transistor is turned on, and the bleed path is activated.

8. The open-drain output driver circuit with a constant voltage slew rate according to claim 2, wherein as the path current of the pull-up path increases, a gate-source voltage of the fourth switch transistor rises, and an on-resistance of the fourth switch transistor as a switch decreases; and a higher current shunted by the bleed path indicates a greater extent of slowing down a charging speed of the target node.

9. The open-drain output driver circuit with a constant voltage slew rate according to claim 2, wherein in response to that a current shunted by the bleed path is greater than a preset current value, the path current of the pull-up path decreases, voltages at two terminals of the second resistor drop, a gate-source voltage of the fourth switch transistor drops, and an on-resistance of the fourth switch transistor as a switch increases; and as the current shunted by the bleed path decreases, an extent of slowing down a charging speed of the target node is weakened.
